(19) United States
(12) Patent Application Publication
(10) Pub. No.: US 2015/0203964 A1
(43) Pub. Date: Jul. 23, 2015

(54) Supply Container for a Coating Installation and Coating Installation

(71) Applicant: OSRAM OLED GmbH, Regesburg (DE)

(72) Inventors: Michael Popp, Freising (DE); Marc Philippens, Regensburg (DE)

(73) Assignee: OSRAM OLED GMBH, Regensburg (DE)

(21) Appl. No.: 14/423,685

(22) PCT Filed: Jul. 19, 2013
(86) PCT No.: PCT/EP2013/065293

§ 371 Date: Feb. 24, 2015

(30) Foreign Application Priority Data
Sep. 5, 2012 (DE) 10 2012 215 708.5

(51) Int. Cl. C23C 16/455; B05C 9/02; B65D 85/00

(52) U.S. Cl. CPC C23C 16/45525; B65D 85/70; B05C 9/02

(57) ABSTRACT

A storage vessel is provided for starting material for producing a layer on a substrate by means of a growth process in a coating installation. The storage vessel has an internal volume for the starting material, in which there is a temperature-compensating material which is inert with respect to the starting material. Furthermore, a coating installation having a storage vessel is specified.

This patent application is a national phase filing under section 371 of PCT/EP2013/065293, filed Jul. 19, 2013, which claims the priority of German patent 10 2012 215 708.5, filed Sep. 5, 2012, each of which is incorporated herein by reference in its entirety.

### TECHNICAL FIELD

A supply container for a coating installation and a coating installation are specified.

### BACKGROUND

Atomic layer deposition (ALD) methods can be used to produce very thin functional layers, for example, functional layers which are thin down to monolayers, in a reproducible manner in various technical fields, for example, optics, semiconductor manufacturing and optoelectronics.

The term “atomic layer deposition” encompasses in particular methods in which, for the production of a layer, the starting materials (precursors) which are required for this purpose are conventionally fed alternately in succession rather than at the same time to a coating chamber, also referred to as a reactor, having the substrate to be coated therein. Furthermore, a simultaneous feed of the materials may also be possible. In the process, the starting materials can accumulate alternately on the surface of the substrate to be coated or on the starting material deposited previously, and thereby enter into a bond. It is thereby possible to grow in each case at most a monolayer of the layer to be applied with every repetition of the cycle, that is to say the one-off feed of all the necessary starting materials in successive sub-steps, so that it is possible to effectively monitor the layer thickness through the number of cycles. If a superlattice structure is deposited, a structure with even greater uniformity can be achieved. Furthermore, ALD methods have the advantage that a very conformal layer growth is possible as a result of the fact that the first-fed starting material only accumulates on the surface to be coated and it is only the then-fed second starting material that undergoes reactions with the first starting material, allowing even surfaces with a great aspect ratio to be covered uniformly.

In the field of optoelectronics, this technique is used, for example, in the manufacture of inorganic light-emitting diodes (LEDs) or organic light-emitting diodes (OLEDs), for instance in order to produce barrier layers or nanolaminates, i.e., layer sequences made up of alternate layers with different materials, in the form of thin-film encapsulations on said components. Examples of such barrier layers and nanolaminates can be found in documents WO 2009/095006 A1, also published as U.S. Pat. No. 8,633,585 B2, and DE 102009024411 A1, also published as U.S. 2012/0132953 A1.

Starting materials based on organometallic compounds are conventionally stored in temperature-stabilized supply containers, in order to feed them to the coating chamber as and when required. FIG. 6A shows a conventional supply container 91 for a coating installation, in which there is present an organometallic starting material 92 in liquid and/or solid form, where, depending on the temperature in the supply container 91, the starting material 92 is also partly in a gaseous phase over the liquid or the solid. The supply container 91 is mounted in a thermostatic bath 95, which has as great a thermal capacity as possible, in order to keep the temperature of the starting material 92 in the supply container 91 as constant as possible. The supply container 91 which is thereby temperature-stabilized according to the prior art has at least one line 96, through which the gaseous starting material 92 is conventionally fed by pulse-like opening of a container valve to a gas stream, which carries the material to the coating chamber. Corresponding to the vapor pressure, which is determined by the temperature of the starting material 92 and consequently at least in principle by the temperature of the thermostatic bath 95, a certain amount of the starting material 92 enters the gas stream. As an alternative thereto, gaseous starting material 92 can also be fed purely through its vapor pressure to the coating chamber, without an additional gas stream.

On account of the removal of starting material 92 from the supply container 91, temperature fluctuations occur within the starting material 92 that remains in the supply container 91 in dependence on the duration and frequency of the removal and the geometrical conditions of the supply container 91. In this respect, FIG. 6B shows purely by way of example the temperature profile T of the starting material 92 in dependence on a time t. Here, the regions 60 denote the coating intervals, i.e., the cycles of operation of the container valve, during which some of the starting material 92 is removed from the container 91. The line 61 identifies the equilibrium temperature of the starting material 92 before the coating intervals are performed. During the coating intervals 60, the temperature in the supply container 91 drops, as indicated by the curve 62, as a result of the material removal. The thermostatic bath 95 is provided to compensate for the heat which has escaped. However, in conventional coating installations, temperature regeneration between the coating intervals 60 is usually only partially possible, since the thermal transfer from the thermostatic bath 95 to the starting material 92 in the supply container 91 proceeds only very sluggishly. As a result, in the course of multiple coating intervals 60 there is undefined cooling of the starting material 92 in the supply container 91.

FIG. 6C furthermore shows in qualitative terms, along a line of intersection x, the spatial distribution of the temperature T in the thermostatic bath 95 and at the surface of the liquid starting material 92 in the supply container 91, the position of each of which is indicated by dashed lines. The discussed sluggish heat transfer from the thermostatic bath 95 to the starting material 92 in the supply container 91 gives rise to temperature gradients within the supply container 91, as indicated by the curve 63. The dashed line 64 here denotes the equilibrium temperature in the supply container 91 which, in the absence of coating cycles, corresponds to the temperature of the thermostatic bath 95 which prevails outside the supply container 91. The removal of material during a coating interval and the thermal linking merely of the marginal region of the supply container 91 to the thermostatic bath 95 gives rise at least in qualitative terms to the temperature distribution shown in FIG. 6C within the supply container 91.

FIG. 6C also shows a further supply container 91′, the size of which differs from that of the supply container 91. Different container sizes give rise to different temperature distributions before and after the removal of material, as a comparison of curves 63 and 63′ shows. In this respect, it may even be the case above a certain size of the supply container 91′ that the temperature 63′ of the starting material drops in certain regions below the melting temperature, which is indicated by the line 65. Therefore, the scaling of the size of supply containers may entail problems, since the container-size-dependent temperature reduction can lead to changes in the evaporation rate from the surface of the starting material 92 and even to changes in state in the region 98 shown in FIG. 6A during the removal of material on account of the sluggish supply of heat via the container wall to the starting material 92. Furthermore, this can also lead to uncontrollable chemical reactions of the starting material 92 in the supply container 91.

The undefined cooling of the starting material 92 in the supply container 91 in dependence on the length and frequency of the coating intervals 30 and in dependence on the size of the supply container 91 may lead to a nonuniform layer thickness profile of the layers to be applied, whereby the quality of the layers to be applied may also be affected.

In this respect, so far only the temperature has been measured and controlled, while stabilization of the vapor pressure of the starting material takes place indirectly by way of thermostatic baths, which however, on account of the sluggish heat transfer, lead to the discussed temperature fluctuations and gradients in the supply container. The problem of scaling the size of supply containers is so far unresolved.

### SUMMARY

Embodiments specify a supply container for a starting material for producing a layer on a substrate by use of a growth process in a coating installation. Further embodiments specify a coating installation having a supply container.

According to at least one embodiment, a supply container for a starting material for producing a layer on a substrate by means of a growth process in a coating installation has an internal volume for the starting material. Furthermore, the supply container has a temperature compensation material in the internal volume.

According to at least one embodiment, a coating installation for producing a layer on a substrate by means of a growth process has at least one supply container, in which there are present at least a starting material for the layer and a temperature compensation material.

The features described hereinbelow apply equally to the supply container and to the coating installation having the supply container.

In particular, the temperature compensation material can be inert with respect to the starting material and as a result cannot bring about any change in the starting material through chemical reactions between the temperature compensation material and the starting material. As a result, the temperature compensation material can advantageously be in direct contact with the starting material in the supply container.

The starting material is preferably present in a liquid form in the supply container. In this respect, the supply container is in particular provided with the liquid starting material in the internal volume. The supply container can be heated in particular to a temperature which lies above the melting temperature and below the boiling temperature of the starting material. On account of the temperature-dependent vapor pressure of the starting material, some of the starting material can be present in gaseous form over the liquid phase and be ready for removal. The temperature compensation material preferably has a higher melting temperature than the starting material and is present as a solid at the temperatures which are common in the supply container, in particular at temperatures at which the starting material is liquid.

Furthermore, it may also be possible that at least some of the starting material is present in solid form in the supply container.

It is particularly preferable that the temperature compensation material has a high thermal capacity, preferably a higher thermal capacity than the starting material. In particular, the starting material can be present in liquid form in the internal volume and the temperature compensation material has a higher thermal capacity than the liquid starting material. When starting material is removed from the supply container, in particular starting material present in the vapor phase, this can have the effect that the temperature within the supply container is lowered to a less severe extent than in the case without a temperature compensation material, since the latter can emit thermal energy to the starting material. The removal of starting material from the supply container in successive coating intervals gives rise to pauses, during which the temperature compensation material can then be brought back to its starting temperature. By virtue of the fact that the temperature compensation material is in direct contact with the starting material in the interior of the supply container, it is possible for direct heat transfer and therefore “heating from within” to take place, the latter being effected in addition to the supply of heat from outside, for instance by a thermostatic bath. The temperature compensation material, which furthermore can also be connected to the thermostatic bath by a heat conductor, therefore makes it possible to compensate for both chronological and spatial temperature gradients, in order to thereby at least partially compensate for temperature fluctuations caused by removal processes.

The supply of heat from outside into the internal volume of the supply container makes it possible for the starting material to be heated to the desired temperature. The supply of heat from outside can preferably be effected by means of a thermostatic bath, in which the supply container is arranged. The thermostatic bath can be formed, for example, by a further container, in which the supply container is arranged and which has a heating apparatus and/or a material having a high thermal capacity. Furthermore, the thermostatic bath can be formed, for example, by a heating apparatus, for example, heating sleeves, which at least partially surround the supply container.

According to a further embodiment, the temperature compensation material is present loosely in the internal volume of the supply container. This can mean that the supply container is filled with the temperature compensation material before being filled with the starting material, such that the temperature compensation material can scatter in the starting material depending on the geometrical configuration of the temperature compensation material in the internal volume of the supply container.

According to a further embodiment, the temperature compensation material is at least partially surrounded by the starting material in the internal volume of the supply container. It is thereby possible to achieve an effective transfer of heat from the temperature compensation material to the starting material. In particular, the temperature compensation material can be present in a form at least partially distributed in the starting material, such that it is possible to achieve a spatially uniform transfer of heat from the temperature compensation material to the starting material.

By way of example, the temperature compensation material can float in the liquid starting material. As a result, the temperature compensation material can be distributed uniformly in the starting material. By way of example, the temperature compensation material can float beneath the surface of the liquid starting material on account of buoyant forces or, for example, on account of active mixing in the liquid starting material.

According to a further embodiment, the temperature compensation material can float at the surface of the liquid starting material. By way of example, this can prevent skin formation at the surface of the starting material and also chemical reactions.

According to a further embodiment, the temperature compensation material is present in the supply container as a multiplicity of separate bodies. The separate bodies can be formed, for example, by spheres, ellipsoids, polyhedra or combinations thereof, which can be present either in the form of solid bodies, hollow bodies or in a form filled with a further material. By way of example, the bodies can comprise glass or glass carbon. Furthermore, it is possible that the temperature compensation material comprises a metal melted down in glass. The metal can be formed by steel, for example. Hollow bodies can be distinguished in particular by the fact that they can float at a surface of the starting material.

Furthermore, the temperature compensation material in the internal volume of the supply container can have a reticular form. This can mean in particular that the temperature compensation material is present in the form of a netted fabric or lattice.

The temperature compensation material of reticular form can in this case be arranged within the starting material, in a manner protruding at least partially from the starting material or else on the surface of the starting material.

According to a further embodiment, the temperature compensation material can have a porous surface or can be porous, such that no pure surface and therefore also no change to the surface of the starting material in liquid form can arise, as a result of which it is possible to prevent skin formation and also chemical reactions at the surface of the liquid starting material.

According to a further embodiment, the supply container has at least one line, for example, a feed line and/or a discharge line. Through the discharge line, vaporous starting material, for example, can be fed from the supply container to a coating chamber of the coating installation. This can be effected, for example, purely on account of the vapor pressure of the vaporous starting material or else by a carrier gas, to which the vaporous starting material is fed by means of the discharge line from the supply container. Furthermore, it is also possible for the supply container to be flushed by means of the carrier gas; this means that carrier gas is conducted via a feed line into the supply container, can become enriched therein with vaporous starting material and can flow through the discharge line together with the vaporous starting material to the coating chamber. The carrier gas can comprise, for example, N₂, H₂, Ar, Ne and/or Kr or can consist thereof.

According to a further embodiment, the growth process carried out in the coating installation for which the supply container is provided is an atomic layer deposition method, and therefore the coating installation is provided for carrying out an atomic layer deposition method. In particular, it is possible for this purpose for at least one or else a plurality of starting materials to be provided in liquid and/or solid form in a respective supply container, it being possible for one, a plurality of or all of the supply containers to comprise an above-described temperature compensation material in the respective internal volume.

According to a further embodiment, the starting material is a metal compound, for example, a halometal compound or an organometallic compound. By way of example, the starting material can comprise or consist of one of the following materials, for which in some cases exemplary substrate temperatures are indicated between parentheses for ALD methods with the respectively indicated further starting materials, to form the materials indicated in each case thereafter:

trimethylaluminum (H₂O; 33° C., 42° C.; Al₂O₃)

trimethylaluminum (O₃; room temperature; Al₂O₃)

trimethylaluminum (O₂ plasma; room temperature; Al₂O₃)

BBr₃ (H₂O; room temperature; B₂O₃)

Cd(CH₃)₂ (H₂S; room temperature; CdS)

Hf[N(Me₂)]₄ (H₂O; 90° C.; HfO₂)

Pd(hfac)₂ (H₂, 80° C.; Pd)

Pd(hfac)₂ (H₂ plasma, 80° C.; Pd)

MeCpPtMe₃ (O₂ plasma+H₂; 100° C.; Pt)

MeCpPtMe₃ (O₂ plasma; 100° C.; PtO₂)

Si(NCO)₄ (H₂O; room temperature; SiO₂)

SiCl₄ (H₂O; room temperature, with pyridine catalyst; SiO₂)

tetrakis(dimethylamino)tin (H₂O₂; 50° C.; SnO₂)

C₁₂H₂₆N₂Sn (H₂O₂; 50° C.; SnOₓ)

TaCl₅ (H₂O; 80° C.; Ta₂O₅)

Ta[N(CH₃)₂]₅ (O₂ plasma; 100° C.; Ta₂O₅)

TaCl₅ (H plasma; room temperature; Ta)

TiCl₄ (H plasma; room temperature; Ti)

Ti[OCH(CH₃)]₄ (H₂O; 35° C.; TiO₂)

TiCl₄ (H₂O; 100° C.; TiO₂)

VO(OC₃H₉)₃ (O₂; 90° C.; V₂O₅)

Zn(CH₂CH₃)₂ (H₂O; 60° C.; ZnO)

Zn(CH₂CH₃)₂ (H₂O₂; room temperature; ZnO)

(Zr(N(CH₃)₂)₄)₂ (H₂O; 80° C.; ZrO₂)

Zr(N(CH₃)₂)₄

By way of example, trimethylindium (TMIn), trimethylgallium (TMGa), trimethylzinc (TMZn), trimethyltin (TMSn) and ethyl-containing derivatives thereof and also diethyltellurium (DETe), diethylzinc (DEZn) and tetrabromomethane (CBr₄) are furthermore also possible.

According to a further embodiment, the substrate to be coated is formed by one or more electronic or optoelectronic components. By way of example, the components can be LEDs, in particular individual light-emitting diode chips, or semiconductor layer sequences in the wafer assemblage or OLED components. By way of example, the layer to be applied can be a barrier layer or part of a layer sequence of a plurality of barrier layers right up to superlattice structures for producing a thin film encapsulation, it being possible, for example, for the barrier layers to each have a thickness of between one atomic layer and 10 nm, with the limits of the indicated range being included. Aluminum oxide, zinc oxide, zirconium oxide, titanium oxide, hafnium oxide and tantalum oxide can be mentioned by way of example as materials for the layers of the thin film encapsulation arrangement.

On account of the temperature compensation material in the supply container, the above-described compensation of temperature fluctuations in particular during the removal of starting material from the supply container can avoid undefined cooling of the starting material. It is thereby possible, in particular in the case of layer systems, to achieve uniform and stable layer thicknesses even over relatively long periods of time and during a multiplicity of coating cycles. Furthermore, there is a more uniform thermal loading of the starting material, as a result of which it is also possible to avoid changes to the surface of the starting material caused by thermal effects, particularly in the case of materials which are stored in the supply container close to the melting point. In addition, it is possible to avoid phase changes of the starting material, which may arise locally in known supply containers, for example, without the temperature compensation material. In contrast to what are termed running/venting operations, a coating installation having the supply container described here can be operated at significantly lower cost, since the outlay in terms of time and material for such flushing operations may be required to a lesser extent or even not at all.

### BRIEF DESCRIPTION OF THE DRAWINGS

Further advantages, advantageous embodiments and developments become apparent from the exemplary embodiments described hereinbelow in conjunction with the figures, in which:

FIGS. 1A and 1B show schematic illustrations of a supply container for a starting material for producing a layer on a substrate by means of a growth process according to one exemplary embodiment;

FIG. 2 shows a schematic illustration of a coating installation having a supply container according to a further exemplary embodiment;

FIGS. 3A and 3B show spatial and chronological temperature distributions;

FIGS. 4 and 5 show schematic illustrations of supply containers according to further exemplary embodiments; and

FIGS. 6A to 6C show a supply container and also chronological and spatial temperature distributions according to the prior art.

In the exemplary embodiments and figures, elements that are identical, of identical type or act identically may be provided in each case with the same reference signs. The illustrated elements and their size relationships among one another should not be regarded as true to scale; rather, individual elements such as, for example, layers, structural parts, components and regions may be illustrated with an exaggerated size in order to enable better illustration and/or in order to afford a better understanding.

### DETAILED DESCRIPTION OF ILLUSTRATIVE EMBODIMENTS

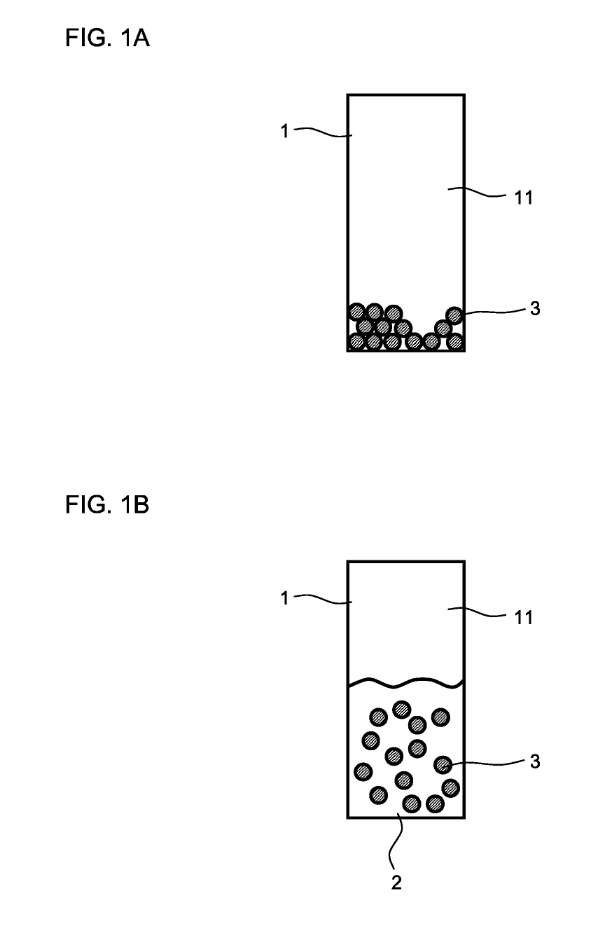

FIGS. 1A and 1B show an exemplary embodiment of a supply container 1 for a starting material 2 for producing a layer on a substrate by means of a growth process in a coating installation.

The supply container 1, which is formed, for example, by a conventional supply container for metal-compound-containing starting materials for coating processes, has an internal volume 11, in which there is present a temperature compensation material 3. FIG. 1A shows the supply container 1 filled only with the temperature compensation material 3, whereas in FIG. 1B the supply container 1 is also filled with the starting material 2 in addition to the temperature compensation material 3 in the internal volume 11.

In the exemplary embodiment shown, the temperature compensation material 3 is arranged loosely in the internal volume 11 of the supply container 1. In particular, in the exemplary embodiment shown, the temperature compensation material 3 is present in the form of a multiplicity of separate bodies, which are formed by spheres. As an alternative thereto, the separate bodies can also be formed by other shapes, for example, ellipsoids, polyhedra or combinations thereof. Depending on the desired floating property and thermal capacity, the separate bodies can be configured in the form of solid bodies, hollow bodies or as filled bodies. In particular, the temperature compensation material 3 is inert with respect to the starting material 2. For this purpose, in the exemplary embodiment shown, the temperature compensation material 3 comprises glass or glass carbon. The glass or glass carbon globules can be filled with a further material, for example, metal. For this purpose, the metal can be present in melted down form in the glass or the glass carbon, for example. By way of example, the separate bodies of the temperature compensation material 3 can be formed by steel spheres melted down in glass.

As is shown in FIG. 1B, the temperature compensation material 3 is preferably distributed as uniformly as possible within the starting material 2, such that the temperature compensation material 3 can emit heat to the starting material 2 with the greatest possible spatial uniformity. By way of example, the starting material 2 can be present in liquid form in the internal volume of the supply container 1. By way of example, the temperature compensation material 3 can float in the liquid starting material 2. Furthermore, the starting material 2 can be present at least also partially in solid form. The temperature compensation material 3 preferably has a higher thermal capacity than the starting material 2.

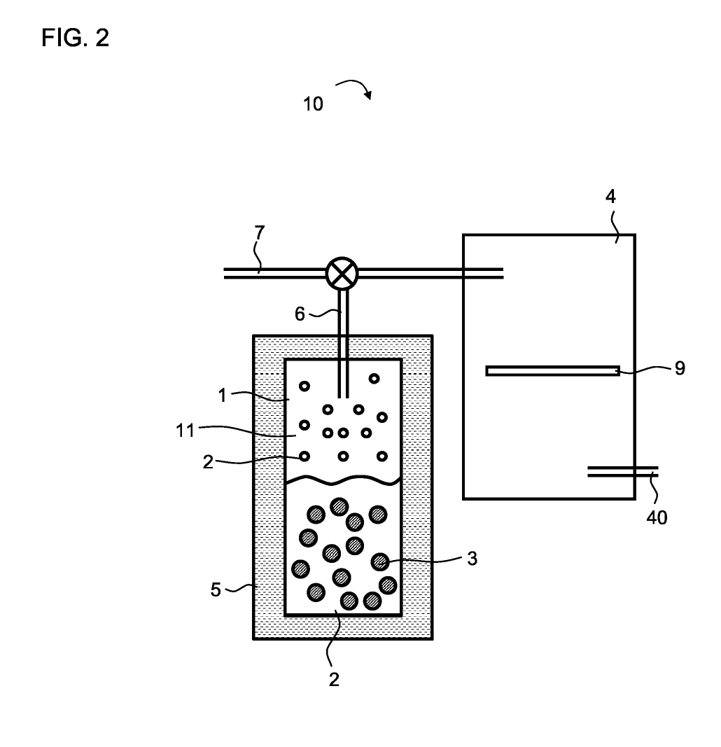

FIG. 2 shows an exemplary embodiment of a coating installation 10 for producing a layer on a substrate 9 by means of a growth process.

In this respect, the coating installation 10 has a coating chamber 4, in which there is arranged a substrate 9 to be coated; the substrate can be formed, for example, by an individual LED or OLED component, a plurality thereof or also, for example, by a semiconductor layer sequence grown onto a semiconductor wafer or one or more semiconductor layers right up to monolayer superlattices. In particular, the coating installation 10 shown in FIG. 2 is used for an atomic layer deposition method (ALD method).

The coating installation 10 has the supply container 1 which has been described in conjunction with FIGS. 1A and 1B and in which there is provided a starting material 2 for the layer to be applied to the substrate 9. The starting material 2, which is formed, for example, by one of the metal compounds mentioned above in the general part, is present in a liquid form in the supply container 1. The temperature compensation material 3 is preferably distributed as uniformly as possible in the starting material 2 and is thereby in direct contact therewith. Furthermore, the starting material 2 can be present at least also partially in solid form.

In order to keep the starting material 2 at the desired temperature, the supply container 1 is located in a thermostatic bath 5 having, for example, a further container with a heating apparatus and/or a material with a high thermal capacity, in order to be able to emit the desired thermal heat to the supply container 1 and therefore to the starting material 2 and the temperature compensation material 3. The vapor pressure of the starting material 2 can be set through the temperature of the thermostatic bath 5, as a result of which some of the starting material 2 can be present in the form of vapor over the liquid phase, as indicated in FIG. 2.

The vaporous starting material 2 can be fed via a line 6, which is in the form of a discharge line, to a carrier gas, for example, N₂, H₂, Ar, Ne and/or Kr, in a line 7 by pulse-like opening of a corresponding valve, as a result of which the starting material 2 can be fed to the coating chamber 4 during the desired coating intervals.

As an alternative thereto, it is also possible that the carrier gas is fed via a further line in the form of a feed line to the supply container 1 (is “bubbled” through the starting material) and can be discharged from the supply container 1 together with the vaporous starting material 2 via the line 6 in the form of a discharge line.

As an alternative thereto, it is also possible that the starting material 2 is fed to the coating chamber 4 purely on account of its vapor pressure without carrier gas.

The coating chamber 4 has a waste gas line 40, via which waste gases and residual gases, for example, volatile reaction products and excess gaseous starting material, can be removed from the coating chamber 4.

The coating installation 10 can have further components, in particular further containers and feed lines for starting materials.

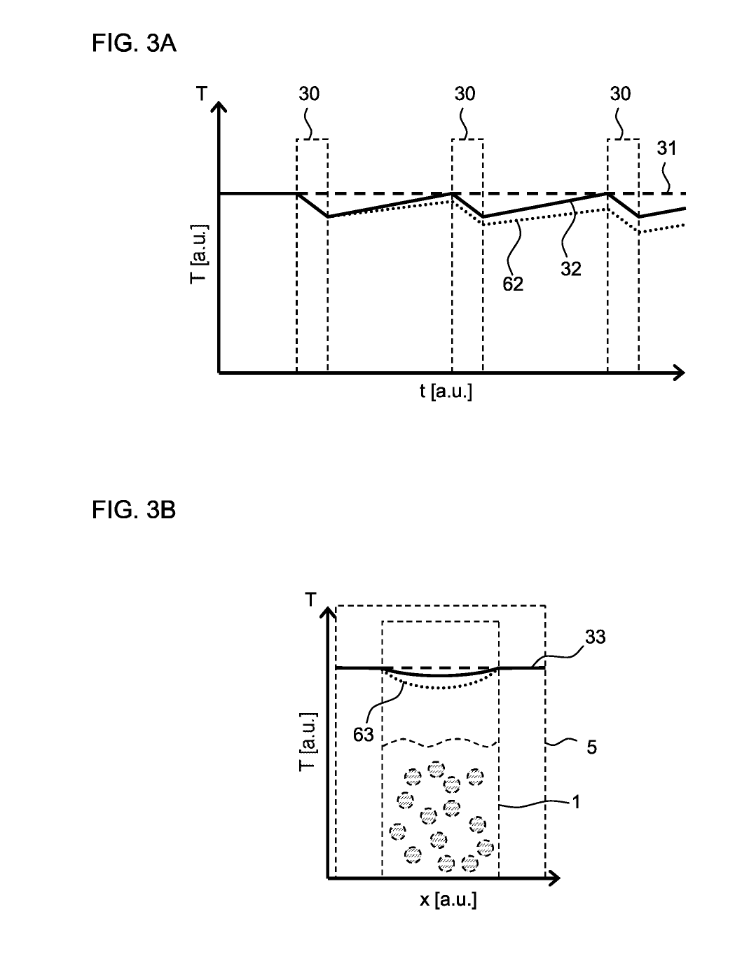

FIGS. 3A and 3B show chronological and spatial temperature distributions as a coating method is being carried out by means of the coating installation 10 shown in FIG. 2.

FIG. 3A shows the chronological profile of the mean temperature T of the starting material 2 in the supply container 1 over a time t over the course of a plurality of coating intervals 30. The equilibrium temperature of the starting material 2 which is set before the coating method is carried out and is intended to be as permanent as possible is denoted by means of the line 31.

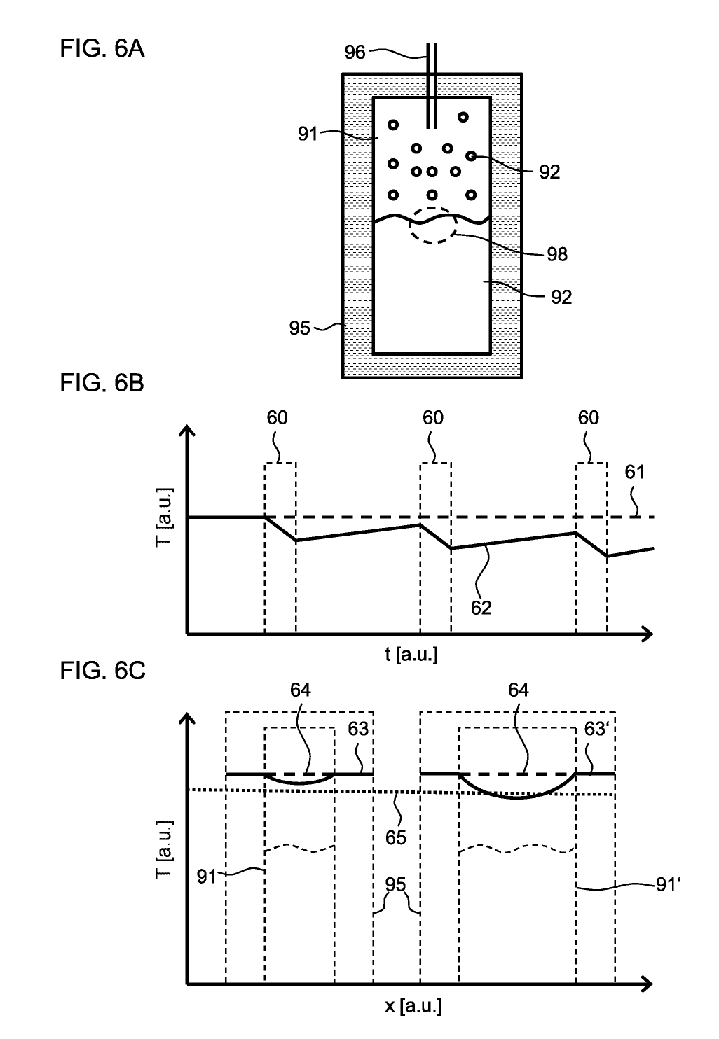

The curve 32 shows the temperature profile during and between the coating intervals 30. Through the removal of gaseous starting material 2 during the coating intervals 30, the temperature T in the supply container 1 and in particular in the starting material 2 which remains in the supply container 1 drops during said intervals. Temperature regeneration is possible between the coating intervals 30, it not only being the case that heat is transferred from the thermostatic bath 5 into the internal volume and therefore into the starting material 2, but also that heat passes from the temperature compensation material 3 to the starting material 2. This can have the effect that, compared to supply containers without a temperature compensation material, the drop in temperature during the coating method can be reduced, as is demonstrated by a comparison of the curve 32 and the curve 62, which is likewise marked and is described above in conjunction with FIGS. 6A to 6C.

FIG. 3B shows the spatial temperature distribution in the thermostatic bath 5 and within the supply container 1 at the surface of the starting material 2, the horizontal line of the curve 33 indicating the equilibrium temperature which is predefined by the thermostatic bath 5. Although, like temperature gradients shown in the prior art as per the curve 63 described above in conjunction with FIGS. 6A to 6C, a temperature gradient is also possible in the case of the supply container 1 described here during and immediately after the removal of starting material 2 from the supply container 1, this temperature gradient turns out to be considerably lower than in the prior art. By virtue of the fact that the temperature compensation material 3 is in direct contact with the starting material 2 within the internal volume 11 of the supply container 1 and acts as an energy store, such that heat can be emitted to the starting material 2 in addition to the thermostatic bath 5 during and after the coating intervals 30, it is possible to achieve a more uniform temperature distribution in the starting material 2. Changes to the phase of the starting material 2 or chemical reactions of the starting material 2 caused by changes in temperature can thereby be avoided.

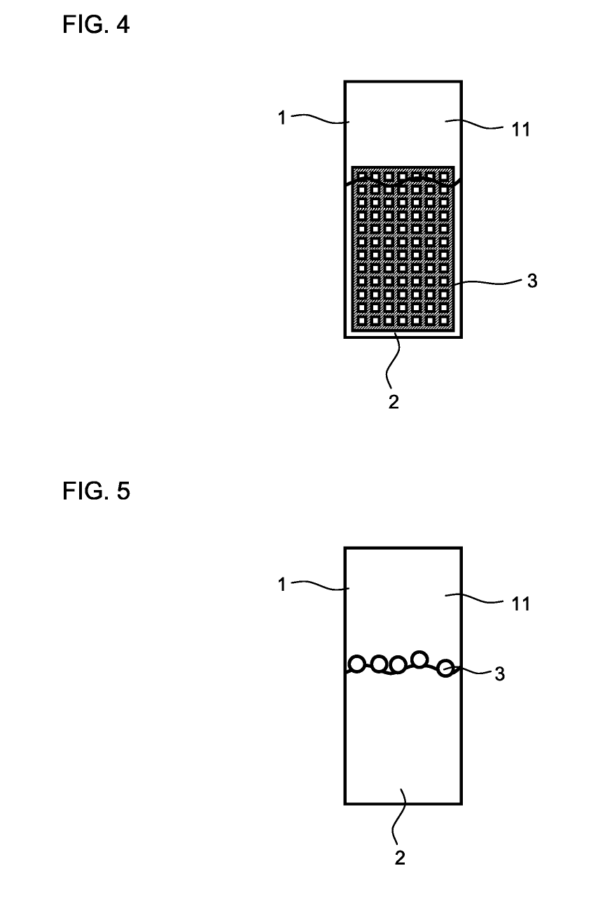

FIGS. 4 and 5 show further exemplary embodiments of supply containers 1; these exemplary embodiments form modifications of the supply container 1 shown in FIGS. 1A and 1B and, like the supply container 1 of the exemplary embodiment shown in FIGS. 1A and 1B, can be used in the coating installation as shown in FIG. 2.

The supply container 1 as per the exemplary embodiment shown in FIG. 4 comprises a temperature compensation material 3, which protrudes partially from the starting material 2 and which is in the form of a lattice, netted fabric or porous material. In addition to the temperature compensation, it is thereby also possible to avoid skin formation at the surface of the liquid starting material 2, since no pure surface and therefore no change to the surface of the starting material can arise. The temperature compensation material 3 can be present in particular, for example, in the form of a lattice or of a netted fabric in the supply container 1, which can be fastened loosely or else in a suitable form in the internal volume 11. As an alternative to the exemplary embodiment shown, the reticular temperature compensation material 3 can also be arranged only at the surface of the liquid starting material 2 or else only submerged in the starting material 2.

As in the exemplary embodiment shown in FIGS. 1A and 1B, the supply container 1 as per the exemplary embodiment shown in FIG. 5 has separate bodies as the temperature compensation material 3, but in the exemplary embodiment shown in FIG. 5 these are in the form of floating inert spheres, which can likewise prevent skin formation and a chemical reaction at the surface of the liquid starting material 2. For this purpose, the separate bodies of the temperature compensation material 3 are formed, for example, as hollow spheres, in particular as hollow glass globules or as glass carbon globules.

As is already the case in the previous exemplary embodiment, a change to the surface during the removal of the starting material 2 can also be reduced or even prevented by the temperature compensation material 3 in the form of hollow spheres.

The exemplary embodiments described in conjunction with the Figures can also be combined with one another and furthermore can alternatively or additionally have further features as per the embodiments described above in the general part.

The invention is not restricted to the exemplary embodiments by the description on the basis of said exemplary embodiments. Rather, the invention encompasses any novel feature and also any combination of features, which in particular includes any combination of features in the patent claims, even if this feature or this combination itself is not explicitly specified in the patent claims or exemplary embodiments.

1-15. (canceled)

16. A supply container for a starting material for producing a layer on a substrate by means of a growth process in a coating installation, wherein the supply container has an internal volume for the starting material, wherein a temperature compensation material is present in the supply container, the temperature compensation material being inert with respect to the starting material.

17. The supply container according to claim 16, wherein the starting material is in liquid form in the internal volume, wherein the temperature compensation material has a higher thermal capacity than the liquid starting material.

18. The supply container according to claim 16, wherein the temperature compensation material is in direct contact with the starting material.

19. The supply container according to claim 16, wherein the temperature compensation material is at least partially surrounded by the starting material.

20. The supply container according to claim 16, wherein the temperature compensation material floats at a surface of the starting material.

21. The supply container according to claim 16, wherein the temperature compensation material is arranged loosely in the internal volume of the supply container.

22. The supply container according to claim 16, wherein the temperature compensation material is present as a plurality of separate bodies.

23. The supply container according to claim 22, wherein the bodies are in the form of spheres, ellipsoids, polyhedra or combinations thereof.

24. The supply container according to claim 16, wherein the temperature compensation material has a reticular form.

25. The supply container according to claim 16, wherein the temperature compensation material has a porous surface.

26. The supply container according to claim 16, wherein the temperature compensation material comprises glass or glass carbon.

27. The supply container according to claim 16, wherein the temperature compensation material comprises a metal melted down in glass.

28. The supply container according to claim 16, wherein the supply container has at least one feed line and/or discharge line.

29. A coating installation for producing a layer on a substrate by means of a growth process, the coating installation having at least one supply container according to claim 16, in which there is present at least one starting material for the layer.

30. The coating installation according to claim 29, wherein the supply container is arranged in a thermostatic bath.

31. A method of making a device, the method comprising:
providing a substrate; and
growing a layer on the substrate by depositing a material from a supply container that stores a starting material and a temperature compensation material that is inert with respect to the starting material.

32. The method according to claim 31, wherein growing the layer comprises performing an atomic layer deposition process.

33. The method according to claim 31, wherein the device comprises a light emitting diode.
